(19) United States
(12) Patent Application Publication
(10) Pub. No.: US 2010/0164645 A1
(43) Pub. Date: Jul. 1, 2010

(54) Tunable Impedance Matching Circuit

(75) Inventors: Kazuhiko Kobayashi, Kawasaki (JP); Yuu Watanabe, Kawasaki (JP); Paulo Augusto Dal Fabbro, Limeira (BR); Maher Kayal, Lausanne (CH)

Correspondence Address: HANIFY & KING PROFESSIONAL CORPORATION, 1055 Thomas Jefferson Street, NW, Suite 400, WASHINGTON, DC, 20007, US

(73) Assignee: FUJITSU LIMITED, Kawasaki-shi, Kanagawa (JP)

(21) Appl. No.: 12/676,335

(22) PCT Filed: Sep. 14, 2007
(86) PCT No.: PCT/JP2007/068487

§ 371 Date: Mar. 3, 2010

(51) Int. Cl. H03H 7/38

(52) U.S. Cl. 333/32

(57) ABSTRACT

The tunable impedance circuit comprises capacitors C1 and C2, an inductor L1, and an inductor L2 magnetically coupled with the inductor L1. The control current I_{control} with variable phase and amplitude from the control circuit 13 flows in the inductor L2. The impedance of the inductor L1 is changed by changing the phase and amplitude of the control current I_{control}. The output impedance is set to an optimum level by setting an effective inductance and an effective quality factor of the tunable impedance circuit 12a to be optimum by means of the phase and amplitude of the control current I_{control} relative to output current I_{RF} of RF PA 11.

### TECHNICAL FIELD

The present invention relates to a tunable impedance matching circuit that is able to adjust impedance.

### BACKGROUND ART

An integrated RF power amplifier (PA) employs an output impedance matching circuit (circuit) to transform the antenna impedance (50Ω in general) into an optimum impedance that promotes, among other characteristics, a good performance in terms of maximum output power, linearity, efficiency and stability. This optimum impedance can be viewed as an optimum resistance (Rₒₚₜ) once it is considered that the impedance matching circuit eliminates the reactive part of the resulting impedance.

The basis for determining Rₒₚₜ is the load line method described by non-patent document 1. Once Rₒₚₜ is determined, this value should be fine-tuned in order to optimize the performance of the PA in terms of, for instance, efficiency or linearity.

The impedance matching circuit can be integrated or can be placed externally to the integrated circuit.

FIG. 1 is a schematic diagram of a typical RF power amplifier and an impedance matching circuit.

In FIG. 1, input and output impedance are assumed to be 50 Ohm. Input impedance matching circuit 10 is provided at the input of RF power amplifier (PA) 11 to match the input impedance of 50 Ohms to an optimum impedance for an input of RF PA 11. Output impedance matching circuit 12 is provided at an output of RF PA 11 to match an output impedance of RF PA 11 to the output impedance of 50 Ohms.

The numerous wireless standards available today and the frequency bands that are subject to their regulations bring about the need for multi-standard, multi-frequency RF power amplifiers (PAs). Such a device can be a wide band PA covering the frequency bands of interest or a narrow band PA whose center frequency can be adjusted when a change in the band of operation occurs. The latter is the principle behind the frequency tunable RF power amplifier.

In most power amplifiers of this kind, the tunability issue is always focused on the output impedance matching circuit design (non-patent documents 2, 3 and patent document 1). This is due to the fact that the values of the reactances comprising the output impedance matching circuit change with frequency and, hence, the load impedance seen by the PA will also vary, thereby forcing the PA to operate under non-optimal conditions at different bands of operation. In previous implementations of a tunable power amplifier, the output impedance matching circuit is made tunable by employing one or more variable reactances. However, changing capacitances of capacitors causes a decrease in the Q-value of the impedance matching circuit, thereby increasing loss of the impedance matching circuit.

In non-patent document 2, a saturable reactor is used to implement a variable inductor by controlling the permeability of its core through a DC bias current applied into its control winding. The main problem here is that such a device cannot be integrated. Integration of the RF power amplifier together with all other parts of the transceiver is desired for space saving and, consequently, for the possibility of adding more functionality to the device where the transceiver will be used. In this case, CMOS is the technology of choice because of its high level of integration, low cost and high yield. In non-patent document 3, MEMS are used to switch on and off inductors and capacitors, thereby forming a tunable impedance matching circuit. This approach, therefore, relies on the availability of MEMS, which is not the case for standard processes. In patent document 1, several possibilities of variable reactances are proposed, but varying the two capacitors of a n-circuit is the main approach.

Therefore, achieving a frequency tunable RF PA that can be integrated in an IC is important. In order to achieve this, it is vital to solve the problem of how to construct a tunable impedance matching circuit that can be integrated in an IC.

[patent document 1] F. H. Raab, “Electronically tuned power amplifier,” U.S. Pat. No. 7,202,734.

[non-patent document 1] S. C. Cripps, RF Power Amplifiers for Wireless Communications, 1st ed. Norwood: Artech House, 1999.

[non-patent document 2] F. H. Raab and D. Ruppe, “Frequency-agile class-D power amplifier,” in 9th International Conference on HF Radio Systems and Techniques, University of Bath, UK, Jun. 23-26, 2003, pp. 81-85.

[non-patent document 3] J. L. Bartlett, et al., “Integrated tunable high efficiency power amplifier,”

U.S. Pat. No. 6,232,841, May 15, 2001.

### DISCLOSURE OF INVENTION

An object of the present invention is to provide a tunable impedance matching circuit which is easily integrated in an IC.

A tunable impedance matching circuit adjusting the impedance of the input or output of an external circuit according to the present invention, comprises: a first inductor for conducting a current of the external circuit; a capacitor unit connected to the first inductor; a second inductor magnetically coupled with the first inductor, for conducting a control current with a certain phase and amplitude relative to the current of the external circuit; and a control circuit for applying the control current to the second inductor and changing the impedance of the first inductor magnetically coupled with the second inductor by changing either or both of the phase and amplitude of the control current.

According to the present invention, the inductance of the first inductor is changed by changing the phase and amplitude of the control current applied to the second inductor, which is magnetically coupled with the first inductor. Because the impedance can be changed only by changing the current, the configuration is simple and easy to integrate in ICs.

### BRIEF DESCRIPTION OF DRAWINGS

FIG. 1 is a schematic diagram of an RF power amplifier.

FIG. 2 is a schematic diagram of a frequency tunable RF power amplifier with the tunable impedance matching circuit according to the embodiment of the present invention.

FIG. 3 is a schematic diagram of a π impedance matching circuit.

FIG. 4 is a schematic diagram of a tunable inductance based on coupled-inductors.

FIG. 5 is a schematic diagram of the tunable π impedance matching circuit according to the embodiment of the present invention.

FIG. 6 is a layout of the integrated planar-interleaved-square transformer according to the embodiment of the present invention.

FIG. 7 is a circuit diagram of the frequency tunable CMOS RF power amplifier with the tunable impedance matching circuit according to the embodiment of the present invention.

FIG. 8 is a simulation result comparison in terms of output power, efficiency and linearity between the frequency tunable RF power amplifier according to the present invention and a conventional RF power amplifier with fixed output impedance.

FIG. 9 is a circuit diagram of the frequency tunable CMOS RF power amplifier with the possibility of fine tuning the control current according to the embodiment of the present invention.

### BEST MODE FOR CARRYING OUT THE INVENTION

The embodiments of the present invention relate to the tunable impedance matching circuit that is applicable, for example, to the field of RF power amplifiers to be used in wireless transmitters and transceivers and, more specifically, to techniques that allow these amplifiers to operate in different frequency bands with optimal performance.

An RF power amplifier is improved by, for example, making it tunable in frequency within specific operating frequency bands by using the tunable impedance matching circuit of the embodiment. The impedance matching circuit of the embodiment employs coupled-inductors. Via the application of a control current into one of the windings of these coupled-inductors, the impedance matching circuit becomes tunable in frequency, thereby allowing the load impedance of, for example, the power amplifier to be set to an optimum value at each operating band.

In the application of the embodiment of the present invention, a frequency tunable RF power amplifier employing an output tunable impedance matching circuit on the basis of integrated planar coupled-inductors is presented. However, the application of the present invention is not limited by the example below. Further, the example below shows that the tunable impedance matching circuit of the embodiment is used for matching output impedance. However, the tunable impedance matching circuit of the embodiment can be used for matching input impedance as well. Further, the circuit used with the tunable impedance matching circuit of the embodiment can be an arbitrary circuit other than a power amplifier.

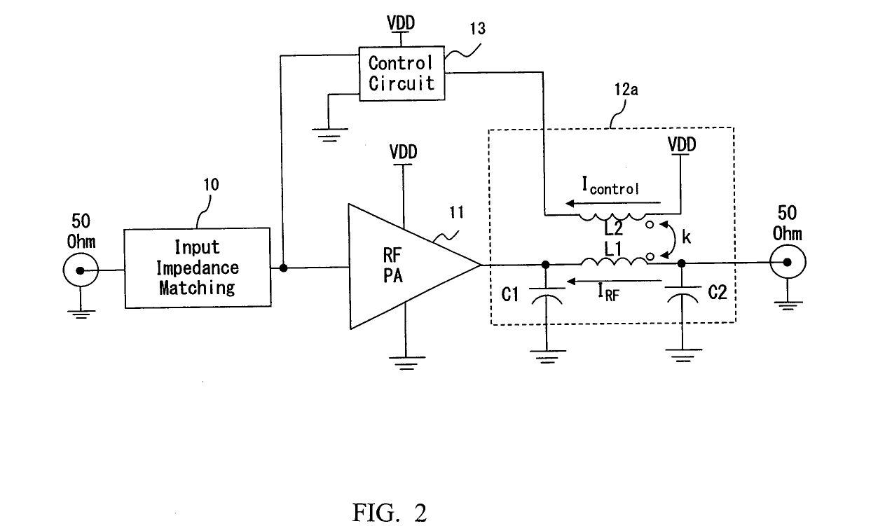

FIG. 2 is a schematic diagram of the frequency tunable power amplifier to which the tunable impedance matching circuit of the embodiment is applied.

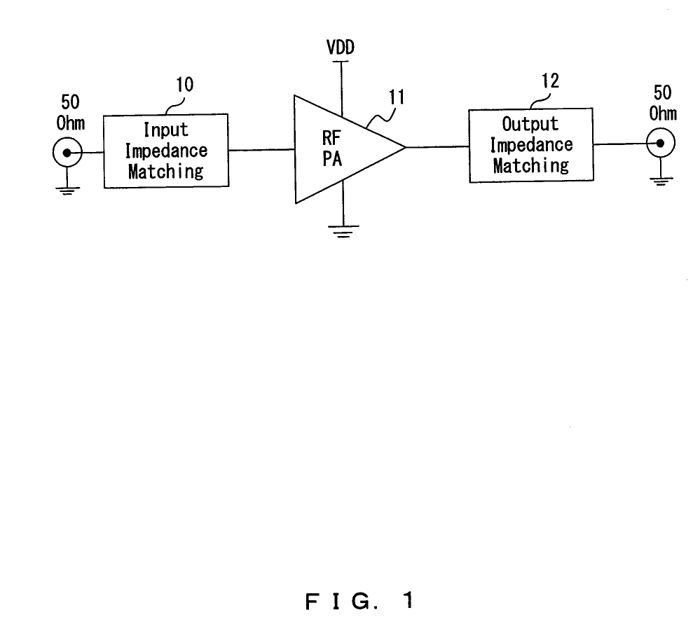

In FIG. 2, like numerals are assigned to like components in FIG. 1 and explanations thereof are omitted.

This amplifier can operate in two or more different bands, for instance, 2.4 GHz and 5.2 GHz, to which are allocated the channels for wireless local area network (WLAN) devices. The advantage of this technique is twofold: first, the possibility of adapting the impedance transformation by the use of only one variable reactance and second, the enhancement of the quality factor (Q) of the inductor [5], thereby reducing matching and resistive losses due to its series parasitic resistance.

The above technology is described in the document below. [5] D. R. Pehlke, A. Burstein, and M. F. Chang, “Extremely high-Q tunable inductor for Si-based RF integrated circuit applications,” in 1997 IEEE International Electron Devices Meeting (IEDM'97) Technical Digest, Washington, D.C., Dec. 7-10, 1997, pp. 63-66.

In FIG. 2, the tunable impedance matching circuit of the embodiment is applied as the output impedance matching circuit 12a. The tunable impedance matching circuit 12a comprises: inductor L1, capacitor C1 connected to an input of the inductor L1, capacitor C2 connected to an output of the inductor L1, and inductor L2 magnetically coupled to the inductor L1 by a coupling constant k and conducting a control current I_{control}. Control circuit 13 receives an output current of the input impedance matching circuit 10 and produces the control current I_{control} to supply the inductor L2. The impedance of the inductor L1 can be changed by changing the amplitude and phase of the control current, which is an alternating current.

As outlined above, adjusting the load impedance through the use of just one variable reactance is possible by employing a n-matching circuit with two shunt capacitors and a series inductor.

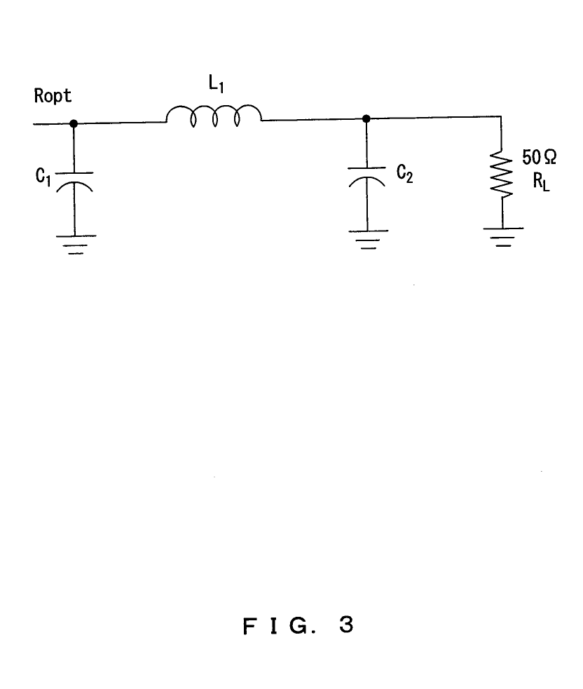

FIG. 3 shows a n-matching circuit.

One reason for choosing such a circuit is that it provides the choice of both the transformation factor (R_{L}>Rₒₚₜ) and its overall quality factor (Q₀). The other reason is that by using adequate capacitor values, the same optimum transformation factor can be obtained for different frequencies by changing just the value of the inductance (L1). This is the objective of a tunable impedance matching circuit and, hence, tuning the inductor is more effective than tuning the capacitors. For example, for an optimum resistance of 20Ω, an antenna impedance should be 50Ω, which results in a transformation factor of 2.5. This transformation factor is obtained by choosing C1=5.65 pF and C2=3.8 pF. If the value of the inductor is varied from 0.4 nH at 5.2 GHz to 1.6 nH at 2.4 GHz, the optimum resistance will be 200 at these two frequencies. If the value of the inductor was invariable and equal to 0.4 nH, the resulting resistance due to the transformation at 2.4 GHz would be 1.50.

One important non-ideality of the n-matching circuit is the finite quality factor Qᵤ of the series inductor. This means that a series resistor R_{L}s is added to the inductor introducing two main shortcomings. The first is the power loss due to dissipation in R_{L}s and the second is the power loss due to mismatching in the circuit introduced by a series resistor placed in the inductor path. Hence, the higher the quality factor of the inductor the better the performance of the power amplifier in terms of maximum output power and efficiency.

Tunable inductors can be built with active inductors [6, 7], MEMS switches [non-patent document 3], saturable reactors [non-patent document 2] and coupledpassive inductors [5, 8-10].

For details, please refer to the documents below.
[6] R. Mukhopadhyay, et al., “Frequency-agile CMOS RFICs for multi-mode RF front-end,” in Proceedings of the 7th European Conference on Wireless Technology, Amsterdam, Holland, Oct. 11-12, 2004, pp. 9-12.
[7] J. H. Sinsky and C. R. Westgate, “A new approach to designing active MMIC tuning elements using second-generation current conveyors,” IEEE Microwave and Guided Wave Letters, vol. 6, no. 9, pp. 326-328, September 1996.
[8] Y.-C. Wu and M. F. Chang, “On-chip high-Q (>3000) transformer-type spiral inductors,” Electronics Letters, vol. 38, no. 3, pp. 112-113, Jan. 31, 2002.
[9] B. Georgescu, et al., “Tunable coupled inductor Q-enhancement for parallel resonant LC tanks,” IEEE Transactions on Circuits and Systems Part II: Analog and Digital Signal Processing, vol. 50, no. 10, pp. 750-713, October 2003.
[10] W. A. Gee and P. E. Allen, “CMOS integrated transformer-feedback Q-enhanced LC bandpass filter for wireless receivers,” in Proceedings of the International Symposium on Circuits and Systems (ISCAS' 2004), vol. 4, Vancouver, Canada, May 23-26, 2004, pp. 253-256.

The only type of tunable inductor that provides the possibility of quality factor enhancement is the coupled passive inductor. Hence, the output impedance matching circuit used in the embodiment employs coupled passive inductors.

Although only n-matching circuits that have two capacitors are shown in the figures, a circuit with only one capacitor is also acceptable.

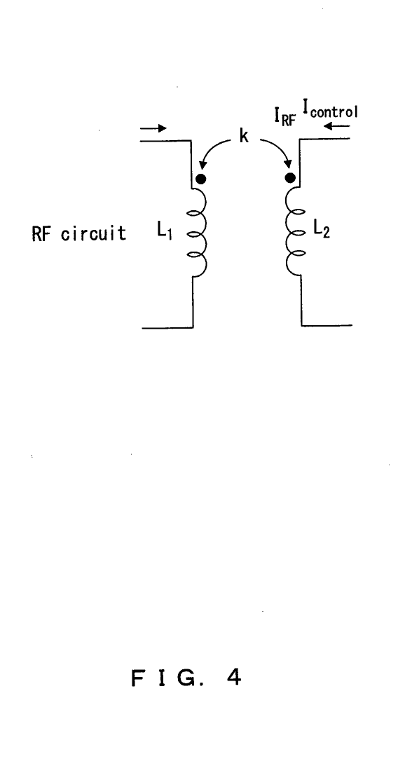

FIG. 4 shows how an inductor can be tuned using mutual inductances.

By applying a control current (I_{control}) through L2 having the same amplitude as the RF current (I_{RF}) that passed through L1, the total inductance seen by the RF circuit connected to L1 becomes L_{eq}=L1+M if the phase shift (φ) between these two currents is zero. In this equation, M stands for the mutual inductance between. L1 and L2 and equals: M=k·√(L1·L2) (where k is the coupling factor between L1 and L2). However, if 9 equals 180 degrees, then the total inductance becomes L_{eq}=L1−M. Therefore, varying the phase shift between these two currents allows tuning of the total inductance seen by the RF circuit from L1−M to L1+M.

Besides the change in the inductance, a resistive part appears in series with the impedance seen by the RF circuit. If the amplitude of I_{control} is r times the amplitude of I_{RF} and if r is varied, the resistive part added by the mutual inductance can attain negative values and decrease the effective series parasitic resistance R_{Ls1}_{_{—}}_{eff} of L1, so that R_{Ls1}_{_{—}}_{eff}<R_{Ls1}.

For L1=L2=L, R_{Ls1}=R_{Ls2}=R_{Ls}, the effective inductance seen by the RF circuit and its corresponding quality factor can be written as:

$${L}_{eff} = L ( 1 + k \cdot r cos φ ) , {Q}_{eff} = \frac{ω L ( 1 + k \cdot r cos φ )}{{R}_{Ls} ( 1 - k \cdot r sin φ \cdot {Q}_{u} )} \qquad ( 1 )$$

The equation above shows that L_{eff} has a tuning range that depends on the amplitude and phase of I_{control} and that its quality factor Q_{eff} can be increased if the term k·r sin φ·Qᵤ is made close to but less than unity, where Qᵤ is a quality factor when I_{control} is not applied.

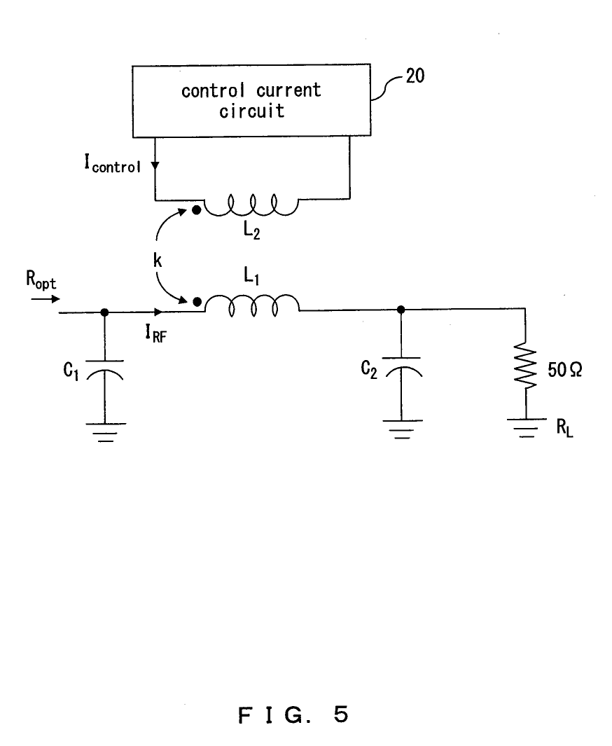

FIG. 5 shows a tunable output n-matching circuit based on coupled-inductors.

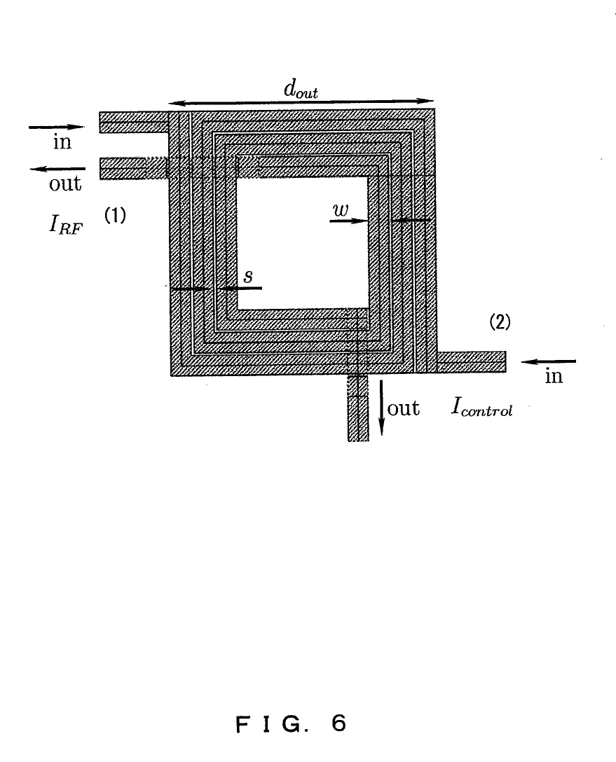

FIG. 6 shows a top-layer planar-interleaved square transformer.

The coupled inductors are implemented with an integrated four-terminal planar-interleaved transformer. The transformer geometry can be square, octagonal or circular. Its windings can be built with a single top metal layer or with stacked metal layers. The choice of the type of transformer depends on the current that it must support and on the value of the inductor, and they will influence the final quality and coupling factors.

The control circuit is responsible for injecting a current I_{control} in L2 with controlled phase shift (φ) and amplitude ratio (r) in relation to I_{RF} in the frequency bands in which the tunable RF power amplifier will be employed.

In FIG. 5, capacitors C1 and C2 and an inductor L1 compose a n-matching circuit. The inductor L1 magnetically couples with an inductor L2. The control current circuit 20 injects the control current I_{control} into the inductor L2. The control current I_{control} is an alternating current with variable amplitude and phase.

In FIG. 6, the integrated four-terminal planar-interleaved transformer is constructed by two winding lines. Each winding line has a width w and both are separated by spaces of width s. The input and output terminals at (1) are those of the inductor L1 and conduct a current I_{RF} of an RF circuit. The input and output terminals at (2) are those of the inductor L2 and conduct the control current I_{control}. The width of the coupled-inductor is dₒᵤₜ.

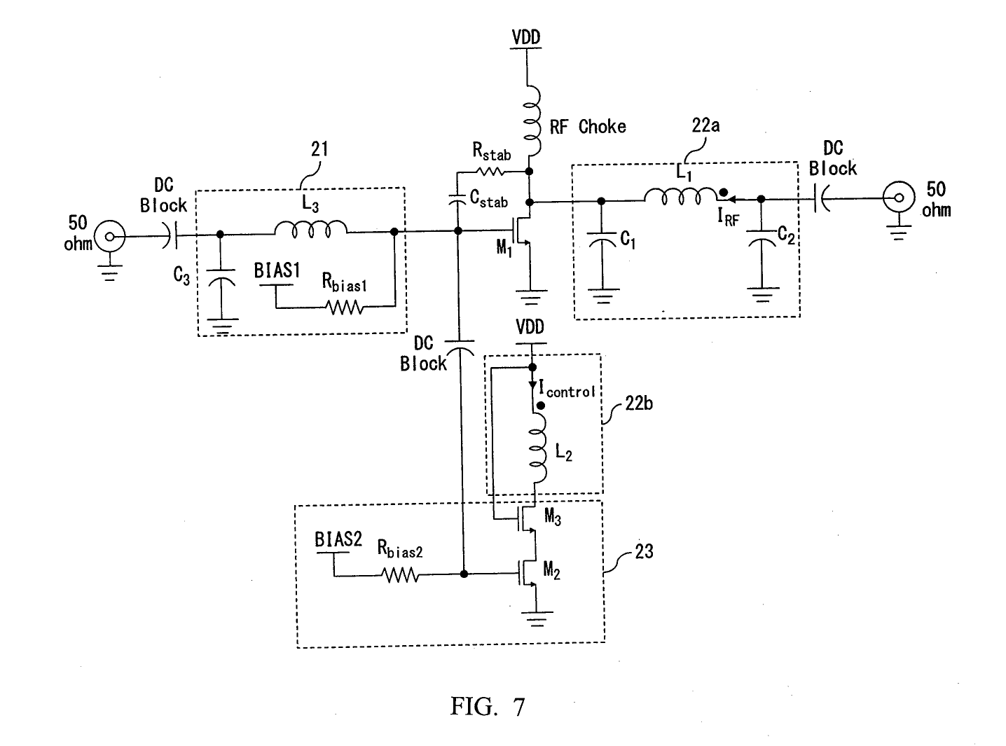

FIG. 7 shows an example circuit diagram of a tunable RF PA with a tunable impedance matching circuit of the embodiment.

In FIG. 7, a concrete circuit configuration of the control circuit is shown. The input impedance matching circuit 21 is a conventional impedance matching circuit that has one capacitor C3 and one inductor L3 and a bias voltage source. The tunable impedance circuit of the embodiment is applied to an output impedance matching circuit 22a and 22b. Even though circuits 22a and 22b are shown as separated circuits, the inductor L1 and inductor L2 of both circuits are magnetically coupled and therefore both circuits are considered to be one circuit. The control circuit 23 comprises two transistors M2 and M3 and a bias voltage source. An RF Choke coil is connected at a drain terminal of the transistor M1.

Transistor M1 is the core of the power amplifier with a fixed input matching made with C3 and L3 and a tunable π output impedance matching circuit formed by C1, L1 and C2. L1 is magnetically coupled to L2 and they are both implemented with an integrated planar transformer like the one in FIG. 6. The control current is related to the RF current because the control circuit composed of the cascoded transistors M2 and M3 have the same input signal as that of the PA. The transistor M3 is provided to increase the isolation of a current flowing through the transistor M2. As alternating components of the input I_{RF} to the transistor M1 are applied to a gate of the transistor M2, The frequency of the control current I_{control} becomes equal to the frequency of the input I_{RF} to the transistor M1. The phase shift and amplitude ratio between currents I_{control} and I_{RF} is established by the dimensions of the transistors and the values of the inductors and capacitors, although the amplitude ratio can be changed by another means. Cascoding in the control circuit and the RC feedback comprising capacitor Cstab and a resistor Rstab in the PA are used to guarantee unconditional stability in all frequencies.

In FIG. 7, the phase of the control current I_{control} is fixed so that a quality factor of the tunable impedance matching circuit 22a and 22b becomes optimum. The inductance of the inductor L1 is controlled by the amplitude of the control current I_{control}, which can be changed by changing the voltage of the bias voltage source BIAS2. Here, the optimum quality factor means that a loss of the tunable impedance matching circuit becomes minimum.

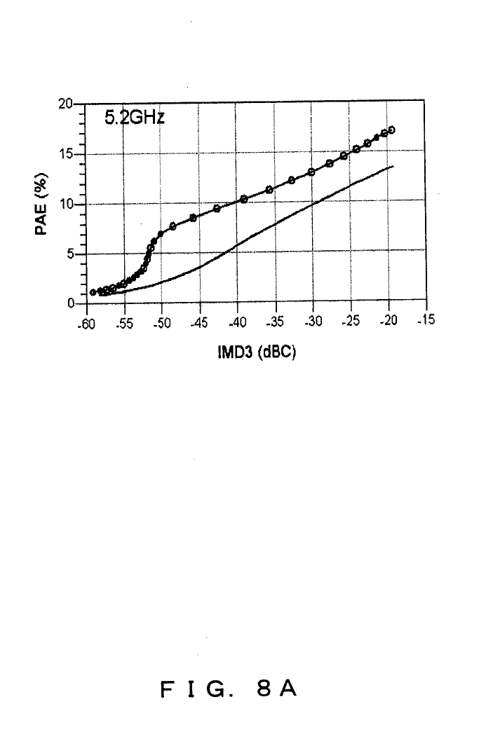

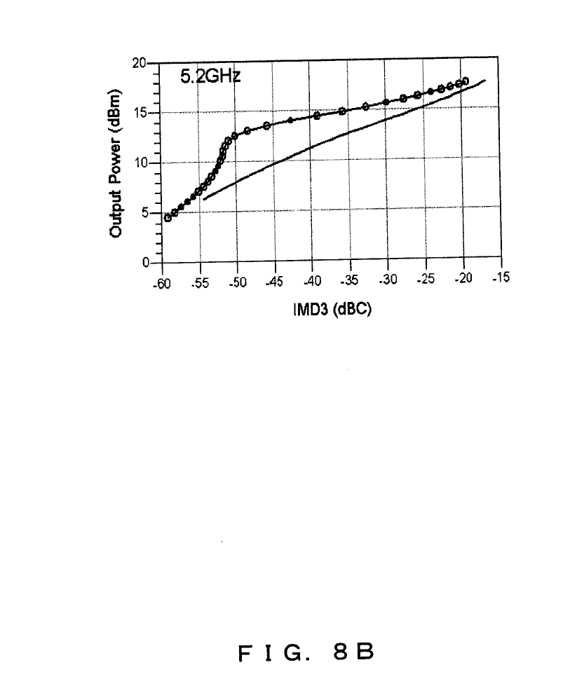

FIG. 8B shows the simulation result for the output power of the power amplifier against third-order intermodulation distortion (IMD3) for the tunable PA and for a similar PA with a fixed output impedance matching circuit (but with the same L1).

In this example, the tunable power amplifier was designed to operate in a 5.2 GHz band.

In FIG. 8A, the measurement of the power-added efficiency (PAE) for the circuit is shown.

From this figure, it can be seen that the tunable PA allows a higher output power to be delivered (considering a limit of −35 dBc IMD3) in the 5.2 GHz band with a higher efficiency.

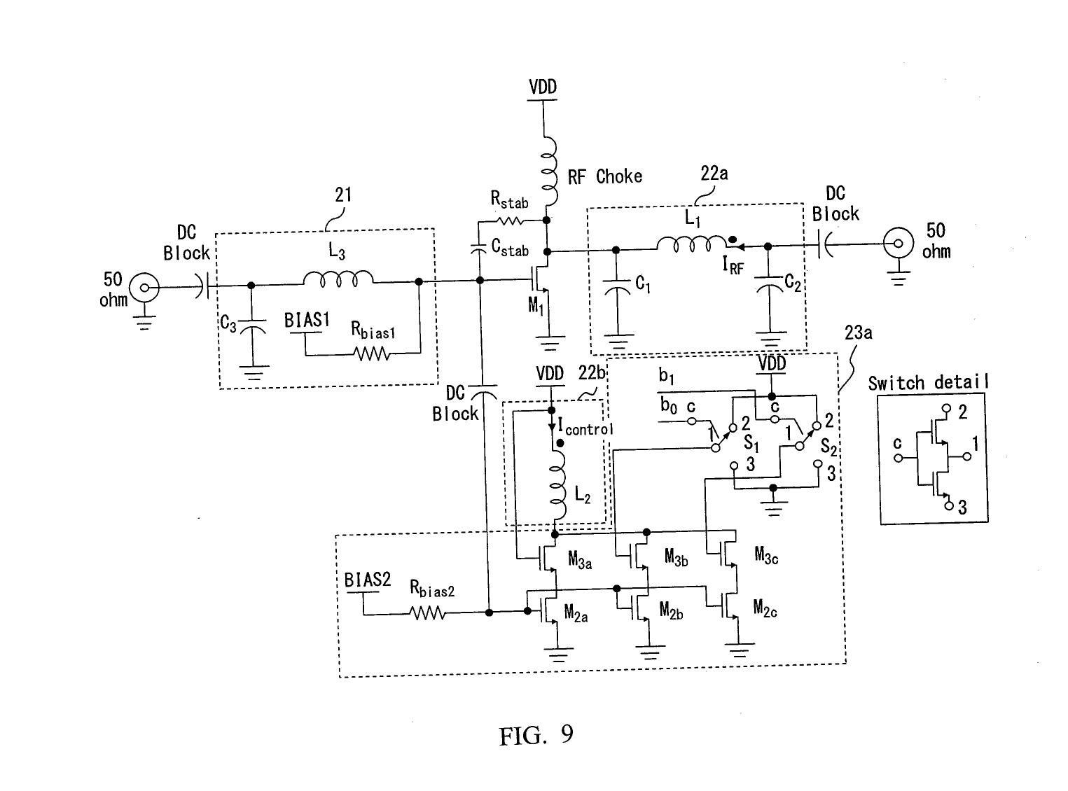

FIG. 9 shows another example circuit diagram of a tunable RF PA with a tunable impedance matching circuit of the embodiment.

Once the components of the circuit of FIG. 7 have been dimensioned, the phase relationship between the control and RF currents are fixed. In order to allow further flexibility to this circuit so that the relationship between I_{control} and I_{RF} can be adjusted, transistors M2 and M3 can be split into M2a, M2b and M2c and M3a, M3b and M3c, forming parallel branches a, b and c as shown in a control circuit 23a of FIG. 9. By connecting the gate of M3b and M3c to ground, these branches are disabled whereas connecting them to VDD enables them. Enabling and disabling these parallel branches that have different phase shift characteristics allow the phase and amplitude relationships between I_{control} and I_{RF} to be varied, thereby allowing the optimum resistance seen by the power amplifier to be adjusted. This flexibility permits the circuit to be fine tuned for proper operation in the frequency range of interest. To enable and disable these branches, switches S1 and S2 can be used. Bits b0 and b1 disable branches b and c when these bits are high and can be implemented as shown in detail in the box of FIG. 9. When these bits are low, these bits enable branches b and c. Transistors M3 and M2 can be split into more branches if more flexibility is required.

1. A tunable impedance matching circuit adjusting an impedance of an input or output of an external circuit, comprising:
a first inductor for conducting a current of the external circuit;
a capacitor unit connected to the first inductor;
a second inductor magnetically coupled with the first inductor, for conducting a control current with a certain phase and amplitude relative to the current of the external circuit; and
a control circuit for applying the control current to the second inductor and changing the impedance of the first inductor magnetically coupled with the second inductor by changing either or both of the phase and amplitude of the control current.

2. The tunable impedance matching circuit according to claim 1, wherein
the capacitor unit includes
a first capacitor connected at an input of the first inductor; and
a second capacitor connected at an output of the first inductor.

3. The tunable impedance matching circuit according to claim 1, wherein
the control circuit sets the phase and the amplitude of the control current so that a quality factor of a circuit comprising the first inductor and the capacitor unit becomes optimum.

4. The tunable impedance matching circuit according to claim 1, wherein
a frequency of the control current is equal to that of the current of the external circuit.

5. The tunable impedance matching circuit according to claim 1 connected at an output of the external circuit.

6. The tunable impedance matching circuit according to claim 1 connected at an input of the external circuit.

7. A frequency tunable amplifier configured with the tunable impedance matching circuit according to claim 1.

8. A frequency tunable amplifier connected with the tunable impedance matching circuit according to claim 1 at its input.

9. A frequency tunable amplifier connected with the tunable impedance matching circuit according to claim 1 at its output.
